(19) United States
(12) Patent Application Publication
(10) Pub. No.: US 2024/0203985 A1
(43) Pub. Date: Jun. 20, 2024

(54) STACKED VERTICAL-TRANSPORT FIELD EFFECT TRANSISTORS (VTFETs)

(71) Applicant: INTERNATIONAL BUSINESS MACHINES CORPORATION, ARMONT, NY (US)

(72) Inventors: Ruilong Xie, Niskayuna, NY (US); Nicholas Anthony Lanzillo, Wynantskill, NY (US); Albert M. Chu, Nashua, NH (US); Brent A. Anderson, Jericho, VT (US); Lawrence A. Clevenger, Saratoga Springs, NY (US)

(21) Appl. No.: 18/081,795

(22) Filed: Dec. 15, 2022

(51) Int. Cl. H01L 27/088; H01L 21/822; H01L 21/8234; H01L 29/417; H01L 29/786

(52) U.S. Cl. CPC H01L 27/088; H01L 21/8221; H01L 21/823475; H01L 21/823487; H01L 29/41733; H01L 29/78642

(57) ABSTRACT

Embodiments are disclosed for a semiconductor device including a top layer having a top vertical-transport field effect transistor (VTFET). Further, the semiconductor device includes a bottom layer disposed beneath the top layer, wherein the bottom layer includes a first bottom VTFET. Additionally, the semiconductor device includes a first frontside contact that wires, through a first backside contact and a first local interconnect, a bottom source/drain epitaxial of the first bottom VTFET to the back end of line interconnect.

### BACKGROUND

The present disclosure relates to semiconductor devices, and more specifically, to stacked VTFETs for semiconductor devices.

Semiconductor devices (devices) can include computer processors, computer memories, and the like. These devices can include field effect transistors (FET), which enable the processing and data storage of a computer processor and memory by controlling current flowing from source to drain. The FET controls current flow by using an electric field.

As stated previously, semiconductor devices, such as computer memory and processors, use field effect transistors to control current flow by using an electric field. More specifically, these semiconductor devices can use vertical-transport FETs (VTFETs). A VTFET uses layers of transistors positioned in a perpendicular direction to the carrier wafer. This change in positioning (in comparison to traditional FETs) can make it possible to relax physical constraints on elements of the FET, (e.g., transistor gate length, spacer thickness, contact size). In this way, the VTFET can provide improved computational performance and reduce energy consumption.

In discussing semiconductor devices, it can be useful to describe them with respect to specific perspectives. For example, semiconductor devices can be described with respect to having a backside and a frontside. The backside and the frontside can represent a perspective with respect to specific elements of the device, i.e., the backside interconnect and the back end of line (BEOL) interconnect, respectively. Thus, the term, frontside, refers to the BEOL interconnect, which is formed above the middle-of-line (MOL) contacts. Conversely, the term, backside, refers to the backside interconnect, which is under the device region (under the source/drain or gates).

Having the backside interconnect can reduce the amount of wiring in the frontside. However, it can still be challenging to wire the VTFET because providing more transistors in the same (or, more limited) space, means more wiring between the source/drain epitaxials (S/D epis) of these transistors and: the frontside, and backside, of the semiconductor device. As the transistors in this position include top and bottom S/D epis, the top S/D epis may be wired to the frontside (i.e., BEOL interconnect) through frontside contacts. Similarly, the bottom S/D epis may be wired to the backside interconnect through backside contacts. However, it can be challenging to wire: top S/D epis to the backside interconnects, and bottom S/D epis to the frontside BEOL interconnect.

### SUMMARY

Embodiments are disclosed for a semiconductor device including a top layer having a top vertical-transport field effect transistor (VTFET). Further, the semiconductor device includes a bottom layer disposed beneath the top layer, wherein the bottom layer includes a first bottom VTFET. Additionally, the semiconductor device includes a first frontside contact that wires, through a first backside contact and a first local interconnect, a bottom source/drain (S/D) epitaxial (epi) of the first bottom VTFET to the back end of line (BEOL) interconnect. Advantageously, such embodiments can provide wiring to top and bottom S/D epis of VTFETS in semiconductor devices that provide improved performance and energy efficiency over current semiconductor devices.

Embodiments are disclosed for a semiconductor device including a top layer having a top vertical-transport field effect transistor (VTFET). Further, the semiconductor device includes a bottom layer disposed beneath the top layer, wherein the bottom layer includes a first bottom VTFET. Additionally, the semiconductor device includes a first frontside contact that wires, through a first backside contact and a first local interconnect, a bottom source/drain (S/D) epitaxial (epi) of the first bottom VTFET to the back end of line (BEOL) interconnect. Further, the bottom layer includes a second bottom FET and a backside interconnect. Additionally, the semiconductor device includes a second frontside contact that shorts a bottom S/D epi of the first top VTFET to a top S/D epi of the second bottom VTFET to the BEOL interconnect. Advantageously, such embodiments can provide wiring to top and bottom S/D epis of VTFETS in semiconductor devices that provide improved performance and energy efficiency over current semiconductor devices.

Embodiments are disclosed for a method for fabricating a semiconductor device. The method includes forming a first dummy interconnect for a bottom S/D epi of a first bottom VTFET. The first dummy interconnect includes an interconnect placeholder material. The method also includes generating a first contact opening that exposes a bottom S/D epi of the first bottom VTFET and the first dummy interconnect. Additionally, the method includes removing the first dummy interconnect. Further, the method includes performing backside contact metallization to generate a first backside contact that wires the bottom S/D epi of the first bottom VTFET to a first local interconnect that is wired to a first frontside contact that is wired to a back end of line (BEOL) interconnect. The first backside contact is generated in a region formerly occupied by the removed first dummy interconnect and the first contact opening. Advantageously, such embodiments can provide wiring to top and bottom S/D epis of VTFETS in semiconductor devices that provide improved performance and energy efficiency over current semiconductor devices.

Embodiments are disclosed for a method for fabricating a semiconductor device. The method includes forming a first dummy interconnect for a bottom S/D epi of a first bottom VTFET. The first dummy interconnect includes an interconnect placeholder material. The method also includes generating a first contact opening that exposes a bottom S/D epi of the first bottom VTFET and the first dummy interconnect. Additionally, the method includes removing the first dummy interconnect. Further, the method includes performing backside contact metallization to generate a first backside contact that wires the bottom S/D epi of the first bottom VTFET to a first local interconnect that is wired to a first frontside contact that is wired to a back end of line (BEOL) interconnect. The first backside contact is generated in a region formerly occupied by the removed first dummy interconnect and the first contact opening. Additionally, the method includes forming a first dummy contact that is in contact with the first dummy interconnect. The first dummy contact includes a contact placeholder material that is different from the interconnect placeholder material. Further, the method includes forming a first contact trench that exposes the first dummy contact. Additionally, the method includes removing the first dummy contact. Further, the method includes forming the middle of line (MOL) metallization to generate the first frontside contact in the region formerly occupied by the first dummy contact and the first contact trench. Advantageously, such embodiments can provide wiring to a bottom S/D epi of a VTFET in semiconductor devices that provide improved performance and energy efficiency over current semiconductor devices.

Further aspects of the present disclosure are directed toward computer program products with functionality similar to the functionality discussed above regarding the computer-implemented methods. The present summary is not intended to illustrate each aspect of every implementation of, and/or every embodiment of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a block diagram of an example computing environment, in accordance with some embodiments of the present disclosure.

FIG. 2 is a block diagram of an example stacked vertical-transport field effect transistor (VTFET) device, in accordance with some embodiments of the present disclosure.

FIGS. 3A and 3B are a process flow chart of a method for fabricating an example stacked VTFET device, in accordance with some embodiments of the present disclosure.

FIGS. 4A, 4B, 4C, 4D, 4E, 4F, 4G, 4H, 4I, 4J, 4K, 4L, and 4M, are example fabrication states of an example stacked VTFET device, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the embodiments described. On the contrary, the intention is to cover all modifications, equivalents, and alternatives falling within the spirit and scope of the present disclosure.

### DETAILED DESCRIPTION

As stated previously, the transistor in a VTFET has a top and a bottom S/D epi. As such, the top S/D epis may be wired to the back end of line (BEOL) interconnect through frontside contacts. Further, the bottom S/D epis may be wired to the backside interconnect through backside contacts. However, it can be challenging to wire: top S/D epis to backside interconnects, and bottom S/D epis to BEOL interconnects.

Accordingly, some embodiments of the present disclosure can fabricate a semiconductor device having stacked layers (e.g., top and bottom layers) of VTFETS. These semiconductor devices can include top S/D epis wired to the backside of the semiconductor device. Additionally, these devices can include bottom S/D epis in each layer wired to the frontside. In this way, some embodiments of the present disclosure can provide wiring to top and bottom S/D epis of VTFETS in semiconductor devices that provide improved performance and energy efficiency over current semiconductor devices.

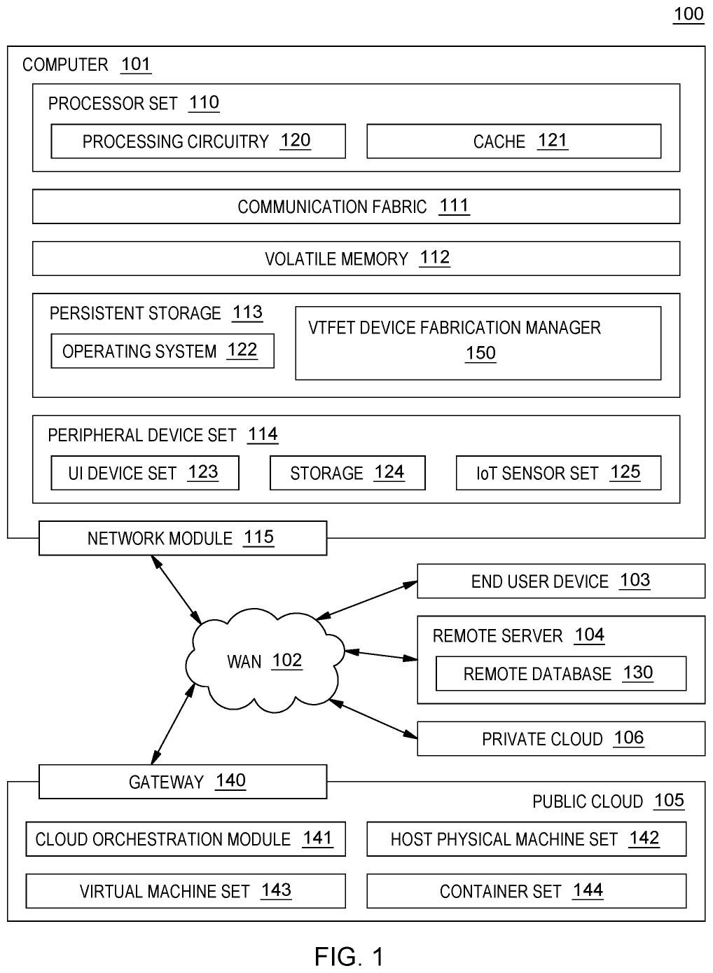

FIG. 1 is a block diagram of an example computing environment 100, in accordance with some embodiments of the present disclosure. Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as stacked vertical-transport field effect transistor (VTFET) device fabrication manager 150. In addition, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and stacked VTFET device fabrication manager 150, as identified above), peripheral device set 114 (including user interface (UI) device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

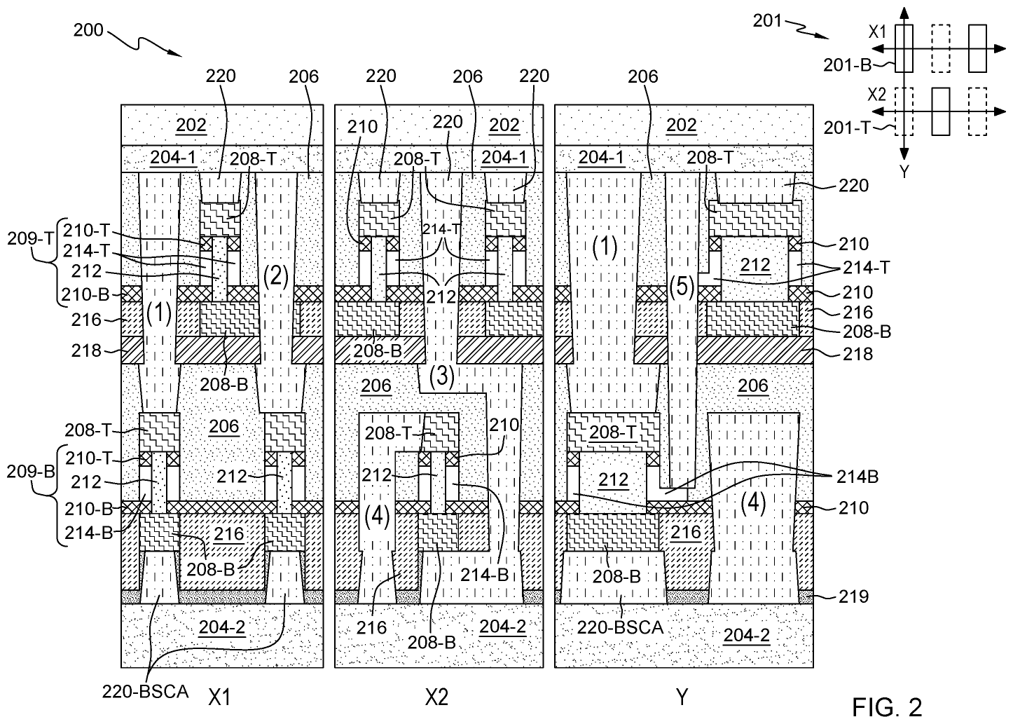

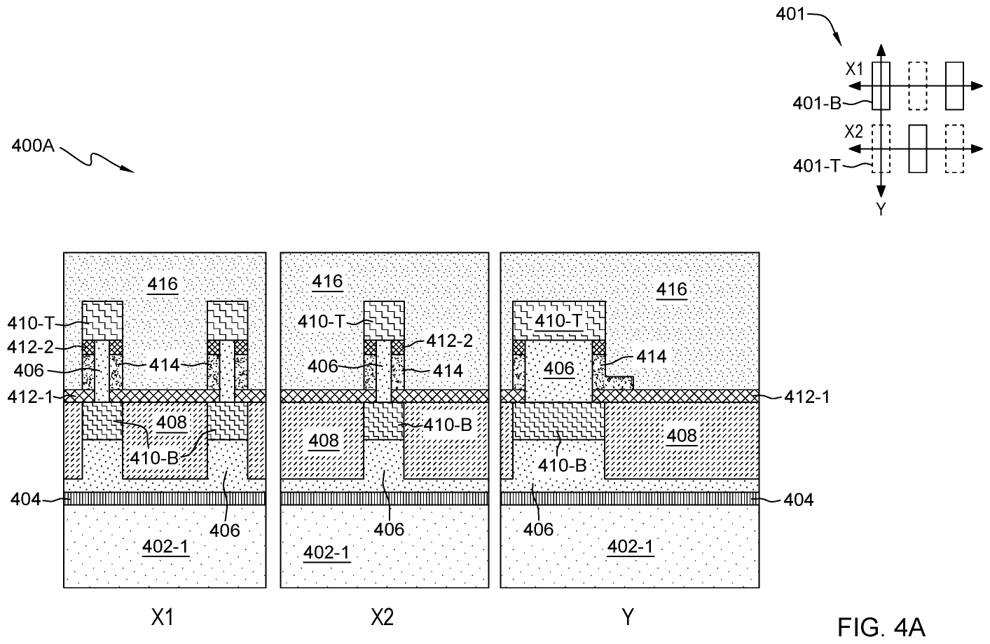

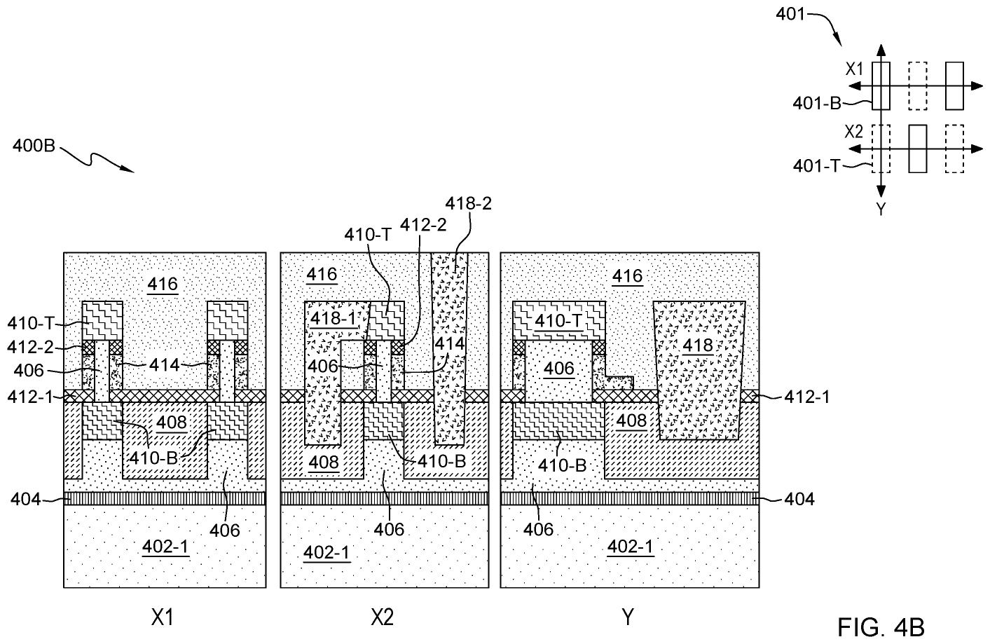

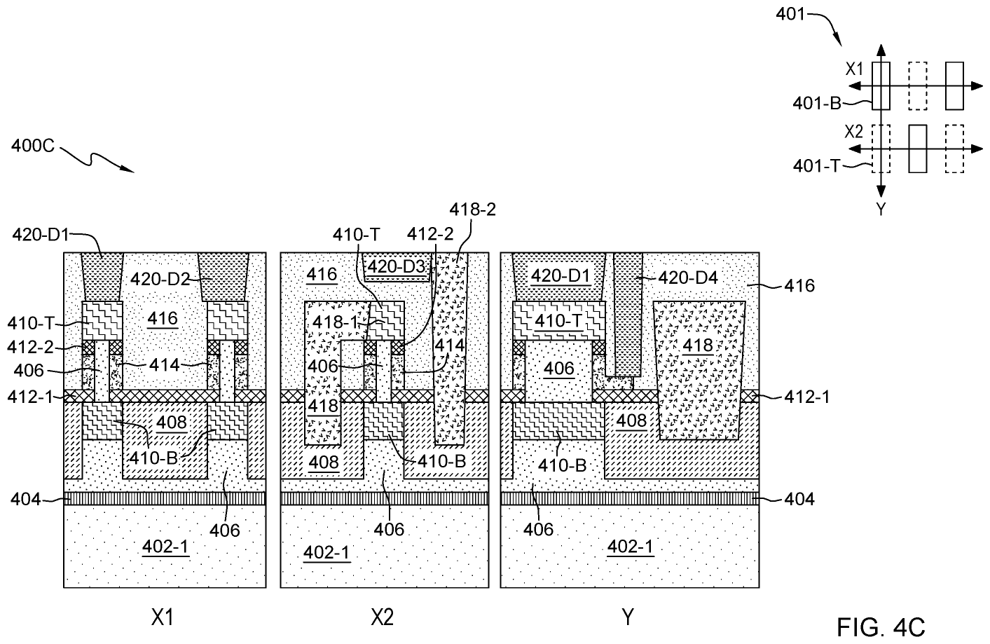

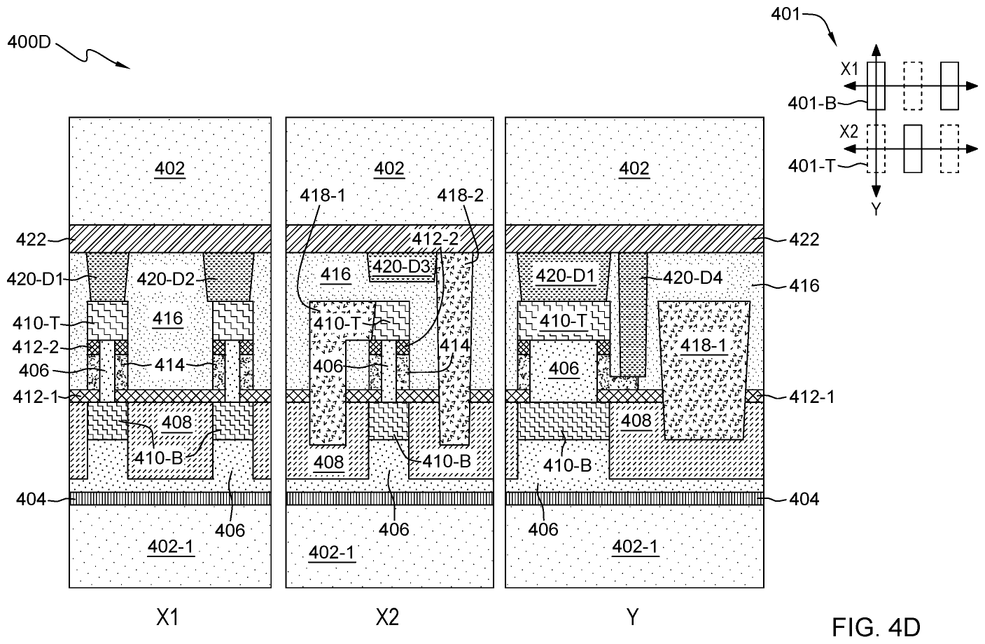

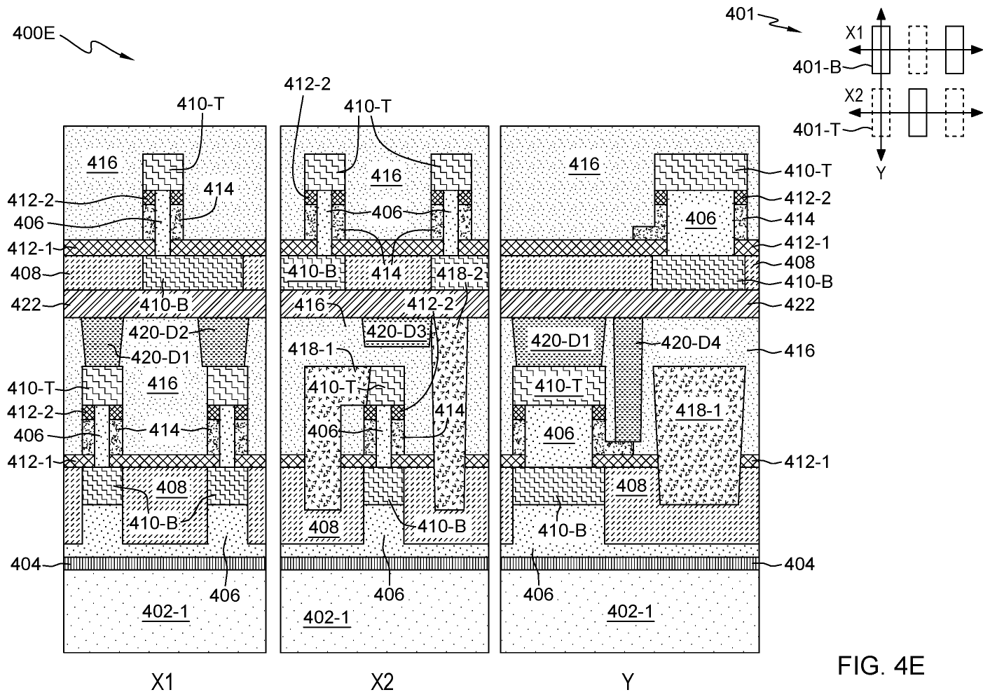

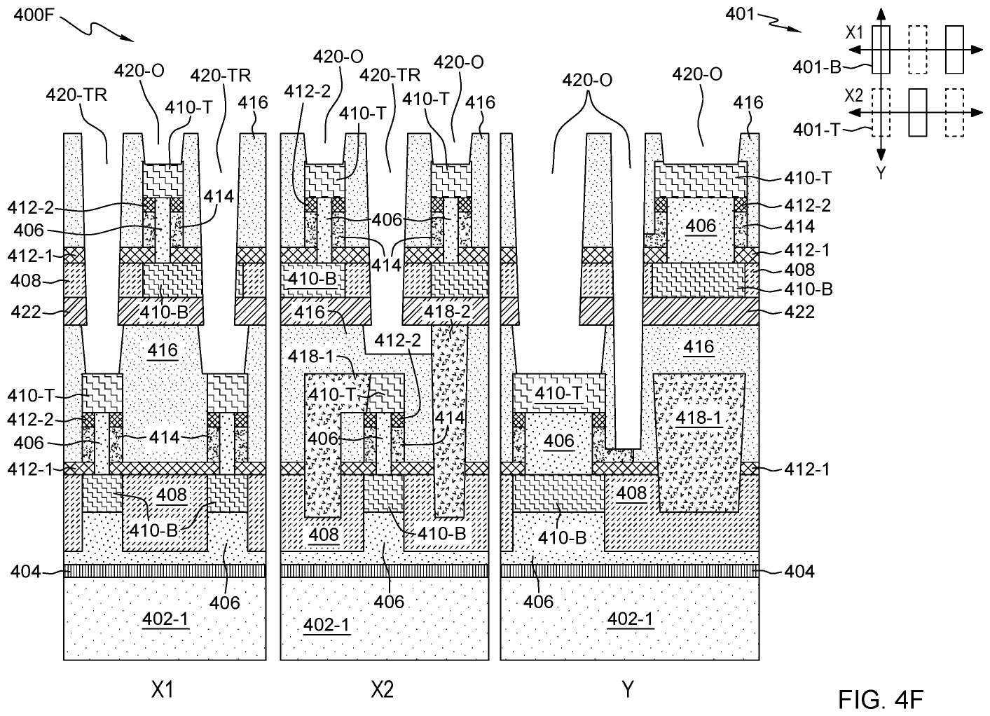

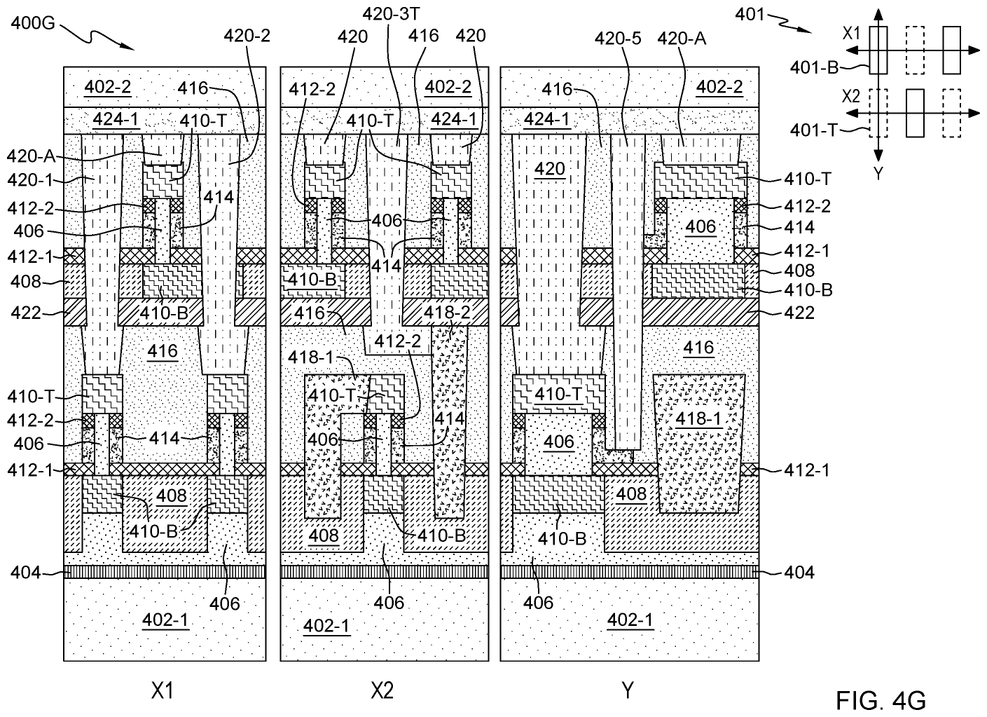

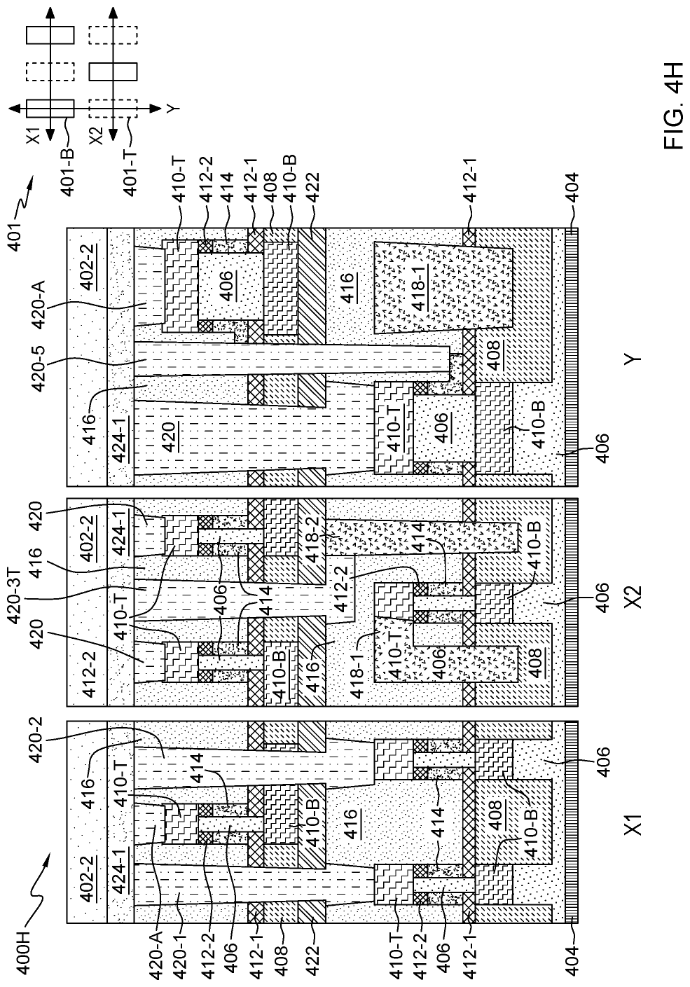

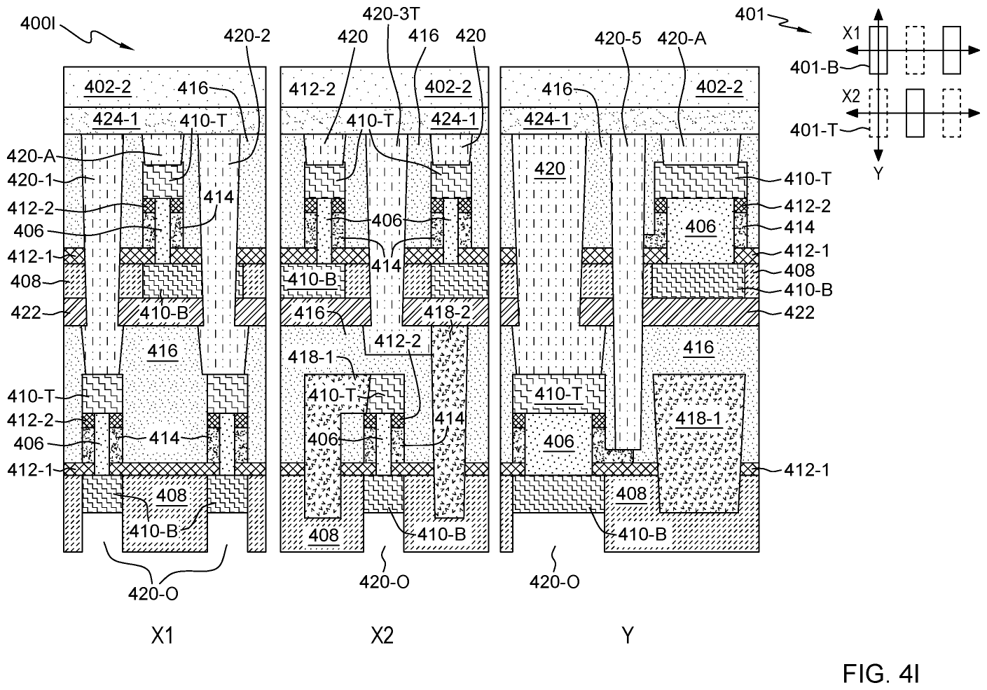

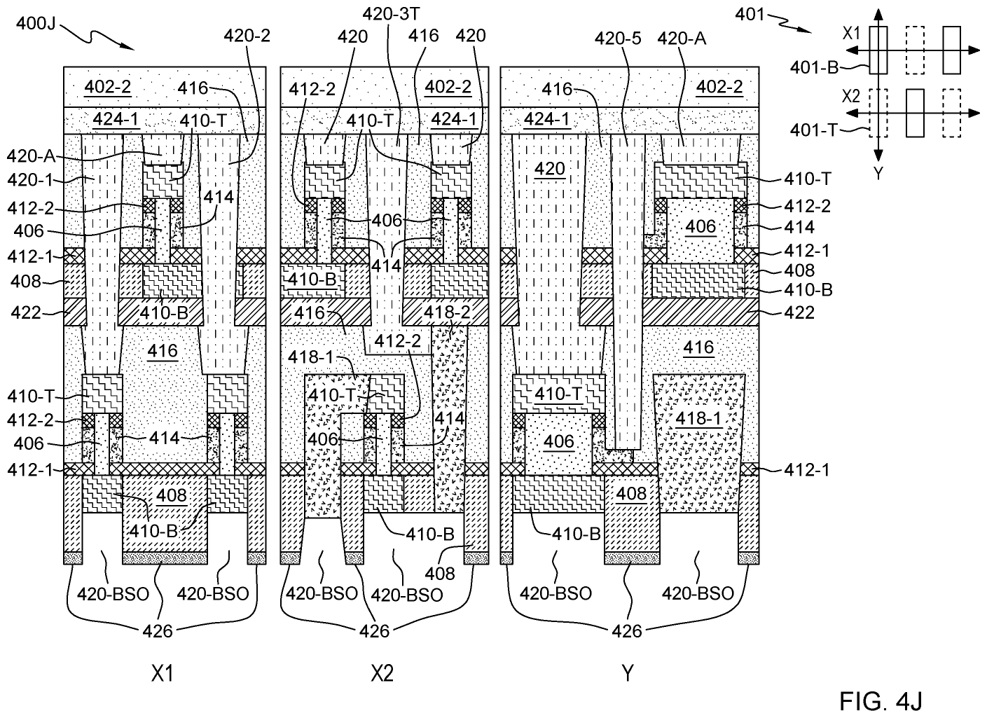

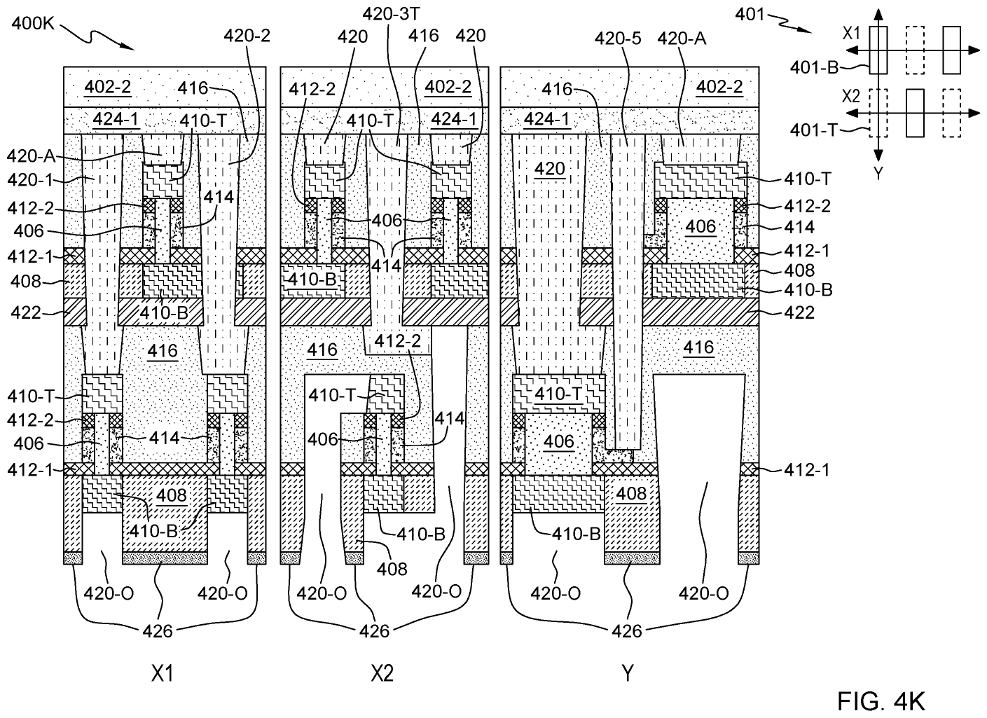

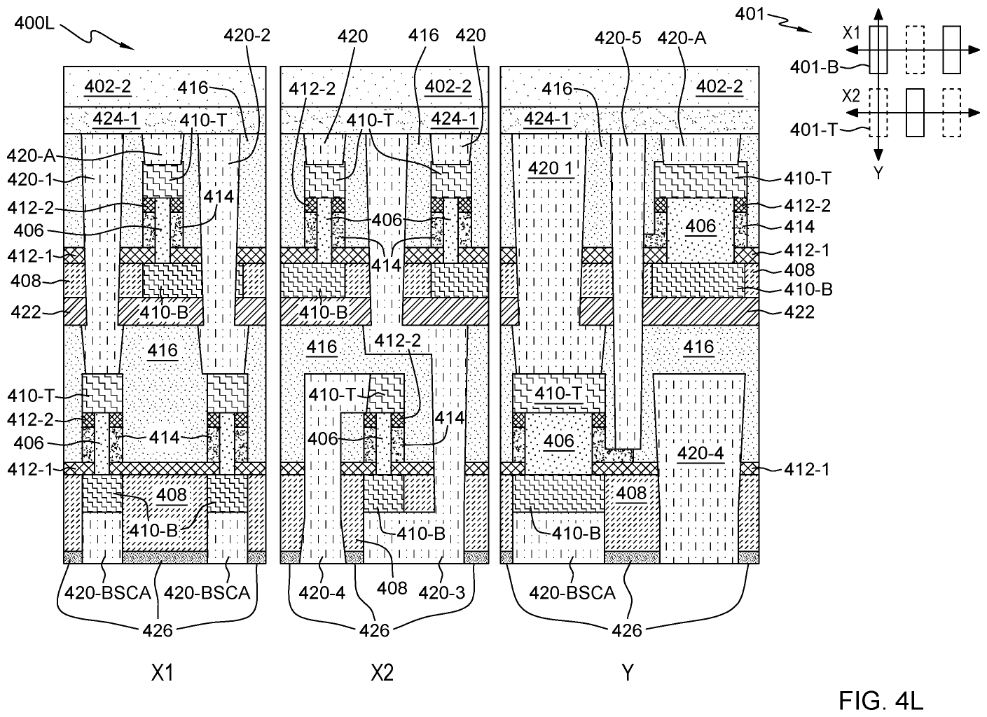

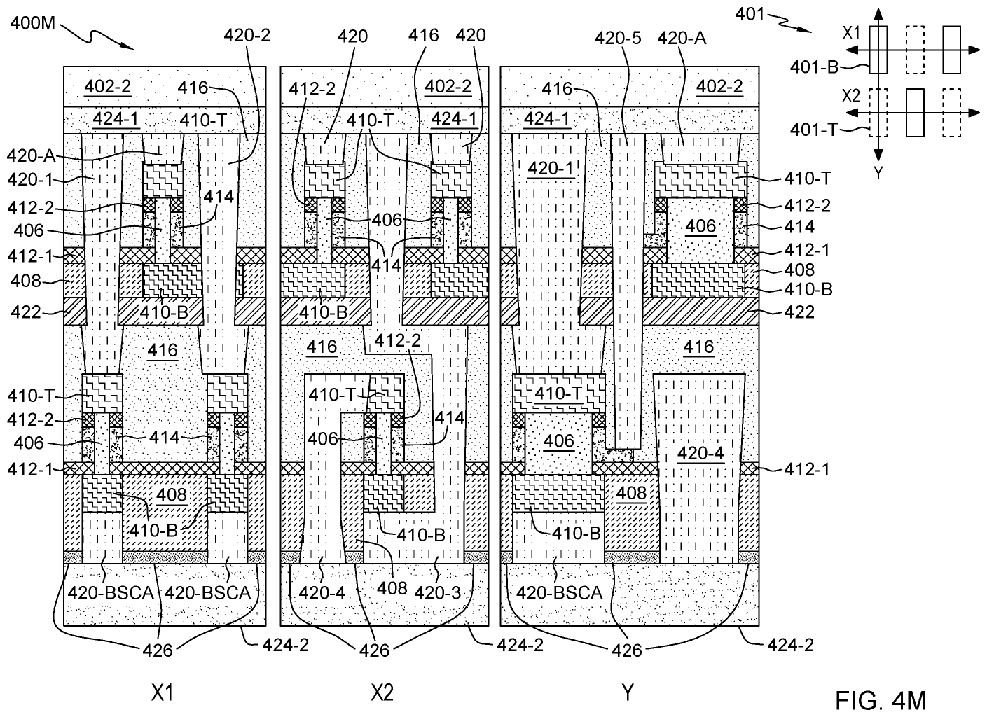

The following descriptions refer to relative locations (e.g., top and bottom) with respect to elements (e.g., gates and epis) of an example semiconductor device. These references are merely intended to describe these elements as shown in FIGS. 2 and 4A-4M, and are not otherwise intended to limit embodiments of the present disclosure.

FIG. 2 is a block diagram of an overhead view 201 and cross-sectional views X1, X2, and Y of an example semiconductor device 200, in accordance with some embodiments of the present disclosure. The example semiconductor device 200 includes a stacked arrangement, thus having a top and bottom layer, separated by a bonding oxide material. Accordingly, the overhead view 201 includes six VTFET pillars, in alternating arrangement. The VTFET pillars include top VTFET pillars 201-T and bottom VTFET pillars 201-B. More specifically, the top VTFET pillars 201-T are represented by the boxes having the dashed lines in 201; and, the bottom VTFET pillars 201-B are represented by the boxes having the solid lines. The top VTFET pillars 201-T and bottom VTFET pillars 201-B each include two layers: a top layer (above the bonding oxide) and a bottom layer (below). However, the top VTFET pillars 201-T include the VTFET in the top layer of the pillar (e.g., above the bonding oxide). Similarly, the bottom VTFET pillars 201-B include the VTFET in the bottom layer (e.g., below the bonding oxide). Additionally, the pillars 201-T, 201-B include the wiring of the sources and drains to: the BEOL, and backside interconnect.

Further, the overhead view 201 includes X1, X2, and Y axes representing cross-sectional views of the semiconductor device 200, with corresponding cross-sectional views below. More specifically, the X1 view represents a cross-gate view of the pillars along the X1-axis of top view 201. Accordingly, the X1 view includes two bottom VTFET pillars 201-B and one top gate pillar 201-T. Similarly, the X2 view includes the pillars along the X2-axis of top view 201. Accordingly, the X2 view includes two top VTFET pillars 201-T and one bottom VTFET pillar 201-B. Further, the Y view represents a cross-S/D view of one top gate pillar 201-T and one bottom VTFET pillar 201-B, as indicated in the top view 201. Further, the X1, X2, and Y views include, from the top of the top layer down, a carrier wafer 202 and BEOL interconnect 204-1. Additionally, these views include, at the bottom of the bottom layer, a backside interconnect 204-2. The carrier wafer 202 can be a silicon (Si) wafer, for example. Further, the backside interconnect 204-2 includes insulators (e.g., backside ILD), and back interconnect which include backside metal wires, and backside metal vias.

As stated previously, the X1 view represents a cross-gate view of a top gate pillar 201-T between two bottom VTFET pillars 201-B, which includes, from top to bottom (as shown), an interlayer dielectric (ILD) 206 surrounding contacts 1, 2, 220, and the top transistor. The contact 220 wires the BEOL-204-1 to a top S/D epi 208-T of the top transistor. The top transistor also includes a top layer VTFET 209-T in contact with the top S/D epi 208-T. Additionally, the top layer VTFET 209-T includes top spacers 210-T, a channel layer (e.g. silicon) 212, high-k gate dielectric and metal gates (HK/MGs) 214-T, and bottom spacers 210-B. Further, the bottom spacers 210-B are in contact with a bottom S/D epi 208-B, which is in contact with the contact 2 and the bonding oxide layer 218. The contact 2, is described in greater detail below.

The contact 1 extends from the top layer to a left bottom transistor. The left bottom transistor includes a top S/D epi 208-T of a left bottom layer VTFET 209-B, the left bottom layer VTFET 209-B, and a bottom S/D epi 208-B of the left bottom layer VTFET 209-B. Accordingly, the contact 1 wires the BEOL 204-1 to the top S/D epi 208-T. The bottom layer VTFET 209-B is similar to the top layer VTFET 209-T, described above. Accordingly, the bottom layer VTFET 209-B includes top spacers 210-T, a channel layer 212 (e.g., silicon), HK/MGs 214-T, and bottom spacers 210-B. Further, the bottom spacers 210-B are in contact with STI layer 216, and bottom S/D epis 208-B. Additionally, the bottom S/D epis 208-B are in contact with backside contacts (BSCA) 220-BSCA. Accordingly, the backside contact 220-BSCA wires the bottom S/D epi 208-B to the backside interconnect 204-2.

Further, the right side bottom transistor, in the X1 view, includes the same elements as the left side bottom transistor. However, instead of the contact 1, the right side bottom transistor includes contact 2. Similar to the contact 1, the contact 2 extends from the top layer to a bottom transistor. However, the contact 2 extends to the bottom right transistor, which is similar to the left bottom transistor. Accordingly, the right bottom layer VTFET is referred to herein as the right bottom layer VTFET 209-B. Further, the contact 2 represents a frontside contact shorting the bottom S/D epi 208-B of the top layer VTFET 209-T to the top S/D epi 208-T of the right bottom layer VTFET 209-B. Additionally, the contact 2 shorts the top S/D epi 208-T of right bottom layer VTFET 209-B to the BEOL interconnect 204-1.

As stated previously, the X2 view represents a cross-gate view of one bottom VTFET pillar 201-B between two top VTFET pillars 201-T, as shown in the top view 201. As such, the X2 view includes similar elements to the X1 view, but in an arrangement having two top VTFET pillars 201-T and one bottom VTFET pillar 201-B. Further, in the X2 view, contact 3 extends from the top layer to the bottom layer. More specifically, the contact 3 wires a bottom S/D epi 208-B of bottom VTFET 209-B to the BEOL interconnect 204-1 through bottom contact, local interconnect, and frontside contact. Additionally, the contact 4 wires the top S/D epi 208-T of the bottom VTFET 209-B to the backside interconnect 204-2 through local interconnect and backside contact.

Further, the Y view represents a cross S/D view of a bottom VTFET pillar 201-B and top gate pillar 201-T, as indicated in the top view 201. Additionally, the Y view includes an intervening space, described below. As shown, the left side of the Y view can represent the bottom VTFET pillar 201-B. Accordingly, the top layer of the bottom VTFET pillar 201-B includes ILD 206 surrounding contact 1, bottom spacers 210-B, shallow trench isolation (STI) layer 216, and bonding oxide layer 218. Additionally, the bottom layer of the bottom VTFET pillar includes ILD 206, contact 1, top S/D epi 208-T, bottom VTFET, bottom S/D epi 208-B, and backside contact 220-BSCA.

In contrast to the left side (e.g., bottom VTFET pillar 201-B), the right side of the Y view can represent the top gate pillar 201-T. As stated previously, the top layer of the top gate pillar 201-T includes ILD 206 surrounding contact 220, top S/D epi 208-T and top VTFET, bottom S/D epi 208-B, STI layer 216, and bonding oxide layer 218. Additionally, the bottom layer of the top gate pillar 201-T includes the ILD 206 surrounding contact 4, the bottom spacers 210-B, STI layer 216, and dielectric layer 219.

The vertical region including the contact 5 represents the intervening space between the top gate pillar 201-T and bottom VTFET pillar 201-B. The top and bottom layers thus include the ILD 206 surrounding contact 5. As shown, the contact 5 provides, through a frontside contact, a shared gate contact between the HK/MG 214-B of the bottom VTFET, and the HK/MG 214-T of the top VTFET.

Accordingly, some embodiments of the present disclosure can include three VTFETs in each of alternating top VTFET pillars 201-T and bottom VTFET pillars 201-B. Thus, using top and bottom layers can provide the space to accommodate wiring to top and bottom S/D epis of VTFETS in semiconductor devices. In this way, such embodiments can provide semiconductor devices with improved performance and energy efficiency over current semiconductor devices.

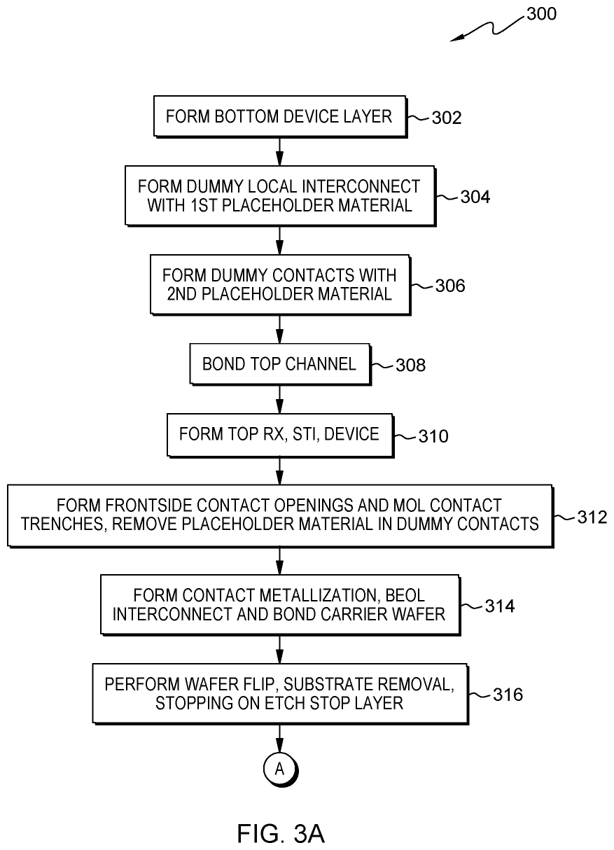

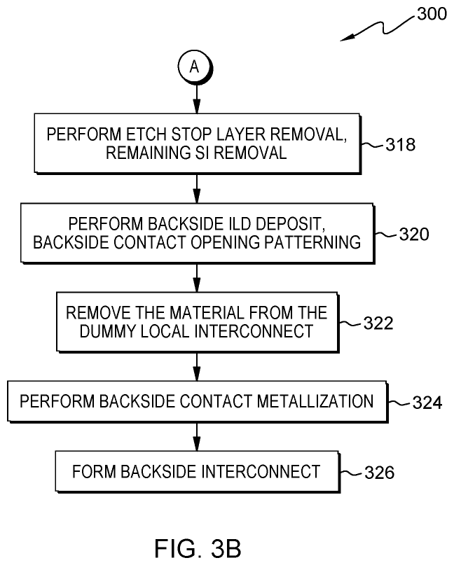

FIG. 3 (encompassing FIGS. 3A and 3B) is a process flow chart of a method 300 for fabricating a semiconductor device, in accordance with some embodiments of the present disclosure. In some embodiments, an example VTFET device fabrication manager, such as the stacked VTFET device fabrication manager 150, described with respect to FIG. 1, can perform the method 300. In this method, the stacked VTFET device fabrication manager 150 can fabricate a semiconductor device, such as the semiconductor device 200, described with respect to FIG. 2. For clarity, the method 300 is described with respect to FIGS. 4A through 4M. It is noted that the example fabrication represented in FIGS. 4A through 4M are merely examples of fabrication states that method 300 may produce. However, some practices of the method 300 may produce other fabrication states.

FIGS. 4A, 4B, 4C, 4D, 4E, 4F, 4G, 4H, 4I, 4J, 4K, 4L, and 4M are example fabrication states of an example semiconductor device, in accordance with some embodiments of the present disclosure. The example semiconductor device can include, for example, the example semiconductor device 200, described with respect to FIG. 2. Referring back to FIGS. 4A through 4M, the example fabrication states 4A-4M include top view 401, and views X1, X2, and Y. Similar to top view 201 of FIG. 2, the top view 401 includes alternating top VTFET pillars 401-A and bottom VTFET pillars 401-B. Additionally, top view 401 includes axes X1, X2, and Y, indicating the orientation of the corresponding cross-sectional views, shown below.

Similar to FIG. 2, in FIGS. 4A-4M, the X1 and X2 views can represent cross-gate views of top and bottom VTFET pillars in corresponding fabrication states. Additionally, the Y view can represent a cross S/D epi view of top and bottom VTFET pillars in these fabrication states. In this way, the example fabrication states 4A through 4M can represent the example semiconductor device (being fabricated) after each operation of the method 300, as described in greater detail below.

Referring back to FIG. 3A, at operation 302, the stacked VTFET device fabrication manager 150 can direct a fabrication tool to form a bottom device layer. Forming the bottom device layer can include forming initial elements of the bottom layer of a device, such as the example semiconductor device 200, described with respect to FIG. 2. For clarity, operation 302 is described with respect to FIG. 4A.

FIG. 4A is an example fabrication state 400A of a semiconductor device being constructed, according to some embodiments of the present disclosure. The example fabrication state 400A may represent the state of the semiconductor device after operation 302. More specifically, the X1, X2, and Y views represent the example fabrication state 400A. As stated previously, the X1, X2, and Y views can represent cross-sectional views of top and bottom VTFET pillars. However, the example fabrication state 400A merely includes a bottom layer, not the top layer. As such, the X1, X2, and Y views merely include bottom VTFET elements, and not top gate elements.

Accordingly, the X1 view includes, from bottom to top (as shown), a substrate 402-1, etch stop layer 404, silicon 406, STI layer 408, bottom S/D epis 410-B, two bottom VTFETs (including bottom spacers 412-1, HK/MGs 414, silicon 406, and top spacers 412-2), top S/D epis 410-T, and ILD 416.

Additionally, the X2 view includes, from bottom to top (as shown), the substrate 402-1, etch stop layer 404, silicon 406, STI layer 408, a bottom S/D epi 410-B, a bottom VTFET (including bottom spacers 412-1, HK/MGs 414, silicon 406, and top spacers 412-2), a top S/D epi 410-T, and ILD 416.

Further, the Y view includes, from bottom to top (as shown), the substrate 402-1, etch stop layer 404, silicon 406, STI layer 408, a bottom S/D epi 410-B, a bottom VTFET (including bottom spacers 412-1, HK/MGs 414, silicon 406, and top spacers 412-2), a top S/D epi 410-T, and ILD 416.

Referring back to FIG. 3A, at operation 304, the stacked VTFET device fabrication manager 150 can direct a fabrication tool to form a dummy local interconnect with a first placeholder material. Forming the dummy local interconnect can involve removing material from the ILD 416, bottom spacers 412-1, and STI layer 408 to make room for the dummy local interconnect. Additionally, forming the dummy local interconnect can involve depositing a first placeholder material in the spaces created by the material removal. More specifically, forming the dummy local interconnect involves patterning trench openings for the dummy placeholder. More specifically, the fabrication tool can pattern a vertical trench opening to the level of the top S/D epi 410-T, and pattern a horizontal trench opening that exposes a side of the top S/D epi 410-T. Additionally, the fabrication tool can fill the trench openings with the first placeholder material. Further, the fabrication tool can perform a chemical mechanical planarization. Also, the fabrication tool can recess the placeholder material in some regions, fill back in the ILD material 416, and perform another CMP. For clarity, operation 304 is described with respect to FIG. 4B.

FIG. 4B is an example fabrication state 400B of a semiconductor device being constructed, according to some embodiments of the present disclosure. In comparison to example fabrication state 400A, the X1 view of example fabrication state 400B is unchanged. However, the X2 and Y views additionally include dummy local interconnects 418-1, 418-2 (collectively referred to as dummy local interconnects 418). The dummy local interconnects 418 can be a semiconductor material, such as, amorphous Silicon (a-Si), amorphous Silicon-Germanium (a-SiGe), titanium oxide (TiOx), aluminum oxide (AlOx), silicon carbide (SiC), and the like. Additionally, the dummy local interconnects 418 can provide a placeholder for local interconnects that are fabricated at a different state. In this way, the example fabrication state 400B can represent a state of the semiconductor device being fabricated after performing operation 304.

Referring back to FIG. 3A, at operation 306, the stacked VTFET device fabrication manager 150 can direct a fabrication tool to form dummy contacts with a second placeholder material. Forming the dummy contacts can involve removing material from the ILD 416 to make room for the dummy contacts, and depositing a second placeholder material in the spaces created by the material removal. For clarity, operation 306 is described with respect to FIG. 4C.

FIG. 4C is an example fabrication state 400C of a semiconductor device being constructed, according to some embodiments of the present disclosure. In comparison to example fabrication state 400B, the X1, X2, and Y views of example fabrication state 400C additionally include dummy contacts 420-D1, 420-D2, 420-D3, 420-D4 (collectively referred to as dummy contacts 420-D). The second placeholder material of the dummy contacts 420-D can include one of the materials described for the first placeholder material of the dummy local interconnects 418. However, the second placeholder material may differ from the first placeholder material. In these ways, the example fabrication state 400C can represent a state of the semiconductor device being fabricated after performing operation 306.

Referring back to FIG. 3A, at operation 308, the stacked VTFET device fabrication manager 150 can direct a fabrication tool to bond a top channel. Bonding a top channel can involve depositing a layer of bonding oxide to the bottom layer shown in example fabrication state 400C. Additionally, bonding the top channel can involve depositing a layer of silicon on the layer of bonding oxide. For clarity, operation 308 is described with respect to FIG. 4D.

FIG. 4D is an example fabrication state 400D of a semiconductor device being constructed, according to some embodiments of the present disclosure. In comparison to example fabrication state 400C, the X1, X2, and Y views of example fabrication state 400D additionally include a bonding oxide layer 422 and a layer of silicon 402 on the bottom layer. In this way, FIG. 4D can represent a state of the semiconductor device being fabricated after operation 308.

Referring back to FIG. 3A, at operation 310, the VTFET device fabrication manager 150 can direct a fabrication tool to form a top active region (RX), STI layer, and the device. Forming the top active region involves top Fin patterning using conventional litho and etch processes, followed by the bottom S/D formation. Further, forming the STI layer can involve forming a trench into the substrate and filling the trench with a dielectric material that isolates the active regions between different semiconductor devices (e.g., VTFETS). Additionally, forming the device can involve generating top and bottom S/D epis, and a VTFET device having top and bottom spacers, and HK/MGs separated by a layer of silicon. For clarity, operation 310 is further described with respect to FIG. 4E.

FIG. 4E is a block diagram of an example fabrication state 400E of a semiconductor device, in accordance with some embodiments of the present disclosure. In comparison to example fabrication state 400D, the views X1, X2, and Y of example fabrication state 400E additionally include an STI layer 408, S/D epis 410-T, 410-B, and VTFETs of the top VTFET pillars 401-T. These VTFETs include top and bottom spacers 412-2, 412-1 (e.g., spacers 412), and HK/MGs 414 separated by a layer of silicon 406. In this way, FIG. 4E can represent a state of the semiconductor device being fabricated after operation 310.

At operation 312, the stacked VTFET device fabrication manager 150 can direct a fabrication tool to form frontside contact openings and middle of line (MOL) contact trenches, and remove the placeholder material in the dummy contacts. Forming frontside contact openings means removing ILD 416 from the top layer to expose the top S/D epis 410-T of the top VTFETS. Further, forming MOL contact trenches means removing material from the ILD 416 (top and bottom layers), bottom spacers 412-1, STI 408, and bonding oxide layer 422, to form trenches for the placement of contacts. For clarity, operation 312 is further described with respect to FIG. 4F.

FIG. 4F is a block diagram of an example fabrication state 400F of a semiconductor device, in accordance with some embodiments of the present disclosure. In comparison to example fabrication state 400E, the X1, X2, and Y views of example fabrication state 400F additionally include frontside contact openings 420-O, and MOL contact trenches 420-TR. Additionally, due to the fabrication tool removing the dummy contacts, the views X1, X2, and Y no longer include the dummy contacts 420-D, described with respect to FIGS. 4C-4E. In this way, FIG. 4F can represent a state of the semiconductor device being fabricated after operation 312.

Referring back to FIG. 3A, at operation 314, the stacked VTFET device fabrication manager 150 can direct a fabrication tool to form MOL contact metallization and BEOL interconnect, and bond a carrier wafer. Forming the MOL contact metallization includes depositing metallic material where the dummy contacts have been removed, and in the MOL contact trenches 420-TR, described with respect to FIG. 4F. Forming the BEOL interconnect can involve fabricating the elements of the BEOL such as, multiple layers of Cu-based metal lines and vias. Further, bonding the carrier wafer involves bonding the carrier wafer to the BEOL. For clarity, operation 314 is further described with respect to FIG. 4G.

FIG. 4G is a block diagram of an example fabrication state 400G of a semiconductor device, in accordance with some embodiments of the present disclosure. In comparison to example fabrication state 400F, the X1, X2, and Y views of example fabrication state 400G additionally include a carrier wafer 402-2, contacts 420, and BEOL interconnect 424-1. Further, the X1 view includes local interconnects 420-1, 420-2, which wire the BEOL interconnect 424-1 to the top S/D epi 410-T of the bottom VTFET. Additionally, the X2 view includes top local interconnect 420-3T, which includes wiring from the BEOL interconnect 424-1 to the dummy local interconnect 418 of the bottom layer. Also, the Y view additionally includes local interconnect 420-5, which provides, through a frontside contact, a shared gate contact between the HK/MG 414-B of the bottom VTFET, and the HK/MG 414-T of the top VTFET. In this way, FIG. 4G can represent the semiconductor device being fabricated after operation 314.

Referring back to FIG. 3A, at operation 316, the stacked VTFET device fabrication manager 150 can direct a fabrication tool to perform a wafer flip and substrate removal, stopping on the etch stop layer. Performing the wafer flip can involve reversing the vertical orientation of the semiconductor device being fabricated. The wafer flip can expose the substrate for removal. Accordingly, performing the substrate removal involves an etching process that removes the substrate material from the exposed surface to the etch stop layer 404. For clarity, operation 316 is further described with respect to FIG. 4H.

FIG. 4H is a block diagram of an example fabrication state 400H of a semiconductor device, in accordance with some embodiments of the present disclosure. As stated previously, operation 316 involves flipping the device being constructed. However, for the sake of clarity, FIG. 4H is shown in the same orientation as in 4A-4G. Further, in comparison to example fabrication state 400G, the X1, X2, and Y views of example fabrication state 400H no longer include the substrate 202-1. In this way, FIG. 4H can represent the semiconductor device being fabricated after operation 316.

Referring back to FIG. 3A, the operation 316 shows a flow to a placeholder A. The placeholder A does not represent an operation of the method, but serves to connect the operations described in FIG. 3A with the other operations of method 300, which are described in greater detail with respect to FIG. 3B.

FIG. 3B is a process flow chart of operations 318 through 326 of the method 300, in accordance with some embodiments of the present disclosure. For clarity, these operations are described with respect to FIGS. 4I through 4M.

The process flow chart of FIG. 3B shows a flow from placeholder A to operation 318. As stated previously, the placeholder A does not represent an operation of the method 300, but serves to connect the operations 302-316 (described with respect to FIG. 3A) with operations 318-326 described below.

At operation 318, the stacked VTFET device fabrication manager 150 can direct a fabrication tool to perform etch stop layer removal, and the remaining silicon (Si) removal. The etch stop layer removal and remaining silicon removal can involve chemical and mechanical processes to remove the materials of the etch stop layer 404 and the silicon 406 in contact with the etch stop layer 404. For clarity, operation 318 is further described with respect to FIG. 4I.

FIG. 4I is a block diagram of an example fabrication state 400I of a semiconductor device, in accordance with some embodiments of the present disclosure. In comparison to example fabrication state 400H, the X1, X2, and Y views of example fabrication state 400I no longer include the etch stop layer and silicon 406. In this way, FIG. 4I can represent the semiconductor device being fabricated after operation 318.

At operation 320, the stacked VTFET device fabrication manager 150 can direct a fabrication tool to perform backside ILD deposit and backside contact opening patterning. Performing backside ILD deposit involves depositing ILD on the STI layer 408. Further, backside contact opening patterning involves removing some portions of the deposited ILD and STI layer 408 to create backside contact openings. For clarity, operation 320 is further described with respect to FIG. 4J.

FIG. 4J is a block diagram of an example fabrication state 400J of a semiconductor device, in accordance with some embodiments of the present disclosure. In comparison to example fabrication state 400I, the X1, X2, and Y views of example fabrication state 400J additionally include, towards the bottom (as shown), backside ILD 426 and backside contact openings 420-BSO. In this way, FIG. 4J can represent the semiconductor device being fabricated after operation 320.

Referring back to FIG. 3A, at operation 322, the stacked VTFET device fabrication manager 150 can direct a fabrication tool to remove the material from the dummy local interconnects 418. Removing this material can involve a chemical etching process and/or mechanical removal. For clarity, operation 322 is further described with respect to FIG. 4K.

FIG. 4K is a block diagram of an example fabrication state 400K of a semiconductor device, in accordance with some embodiments of the present disclosure. In comparison to example fabrication state 400J, the X1 view is unchanged. In contrast, the X2 and Y views no longer include the dummy local interconnects 418 described with respect to FIG. 4B. Accordingly, removing the dummy local interconnects 418 exposes the top local interconnect 420-3T and S/D epi 410-T of the bottom VTFET to the backside contact openings 420-O. In this way, FIG. 4K can represent the semiconductor device being fabricated after operation 322.

Referring back to FIG. 3A, at operation 324, the stacked VTFET device fabrication manager 150 can direct a fabrication tool to perform backside contact metallization. Performing backside contact metallization can involve filling the backside contact openings 420-O (described with respect to FIG. 4K) with conductive metallic material. The conductive metallic material can include, for example, a silicide liner, such as titanium (Ti), nickel (Ni), nickel-platinum alloy (NiPt); a metal adhesion liner, such as titanium nitride (TiNi); or, low resistance metal fills, such as tungsten (W), cobalt (Co), or ruthenium (Ru). For clarity, operation 324 is further described with respect to FIG. 4L.

FIG. 4L is a block diagram of an example fabrication state 400L of a semiconductor device, in accordance with some embodiments of the present disclosure. In comparison to example fabrication state 400K, the X1, X2, and Y views of example fabrication state 400L additionally include contacts and local interconnects in the former backside contact openings 420-O. In the X1 view, the contacts 420-BSCA are each in contact with the bottom S/D epi 410-B of the bottom VTFETs. Additionally, the X2 view includes local interconnects 420-3, 420-4. The local interconnect 420-3 wires the BEOL interconnect 424-1 to the bottom S/D epi 410-B of the bottom VTFET. Further, the local interconnect 420-4 provides backside wiring to the top S/D epi 410-T of the bottom VTFET. Additionally, the Y view includes backside contact 420-BSCA and local interconnect 420-4. In this way, FIG. 4L can represent the semiconductor device being fabricated after operation 324.

Referring back to FIG. 3A, at operation 326, the stacked VTFET device fabrication manager 150 can direct a fabrication tool to form the backside interconnect. Forming the backside interconnect formation can involve fabricating the elements of a backside interconnect such as, metallic lines, ILD material, and a heavy metal layer. For clarity, operation 326 is further described with respect to FIG. 4M.

FIG. 4M is a block diagram of an example fabrication state 400M of a semiconductor device, in accordance with some embodiments of the present disclosure. In comparison to example fabrication state 400L, the X1, X2, and Y views additionally include a backside interconnect 424-2. In this way, the example fabrication state 400M represents an example semiconductor device such as, the example VTFET semiconductor device 200, described with respect to FIG. 2.

A non-limiting list of examples are provided hereinafter to demonstrate some aspects of the present disclosure.

Example 1 is a semiconductor device. The device includes a top layer comprising a top vertical-transport field effect transistor (VTFET); a bottom layer disposed beneath the top layer, wherein the bottom layer comprises a first bottom VTFET; and a first frontside contact (3) that wires, through a first backside contact and a first local interconnect, a bottom source/drain (S/D) epitaxial (epi) of the first bottom VTFET to the back end of line (BEOL) interconnect.

Example 2 includes the device of example 1, including or excluding optional features. In this example, the bottom layer further comprises a second bottom FET and a backside interconnect, and wherein the semiconductor device further comprises a second frontside contact (2) shorting a bottom S/D epi of the first top VTFET to a top S/D epi of the second bottom VTFET to the BEOL interconnect. Optionally, the bottom layer further comprises a third bottom FET, and wherein the semiconductor device further comprises a third frontside contact (1) that wires a top S/D epi of the third bottom VTFET to the BEOL interconnect. Optionally, the first top VTFET is disposed between the second frontside contact and the third frontside contact. Optionally, the device includes a fourth frontside contact (5) that provides a shared gate contact between the first bottom VTFET and the first top VTFET. Optionally, the device includes a second backside contact that wires a top S/D epi of the third bottom VTFET to the backside interconnect through a third local interconnect. Optionally, the device includes a second top VTFET that is wired to the BEOL interconnect through a fifth frontside contact. Optionally, the device includes a third top VTFET that is wired to the BEOL interconnect through a sixth frontside contact. Optionally, the first frontside contact is disposed between the second top VTFET and the third top VTFET.

Example 3 is a method for fabricating a semiconductor device. The method includes forming a first dummy interconnect for a bottom S/D epi of a first bottom VTFET, wherein the first dummy interconnect comprises an interconnect placeholder material; generating a first contact opening that exposes a bottom S/D epi of the first bottom VTFET and the first dummy interconnect; removing the first dummy interconnect; and performing backside contact metallization to generate a first backside contact that wires the bottom S/D epi of the first bottom VTFET to a first local interconnect that is wired to a first frontside contact that is wired to a back end of line (BEOL) interconnect, wherein the first backside contact is generated in a region formerly occupied by the removed first dummy interconnect and the first contact opening.

Example 4 includes the method of example 3, including or excluding optional features. In this example, the method includes forming a first dummy contact that is in contact with the first dummy interconnect, wherein the first dummy contact comprises a contact placeholder material that is different from the interconnect placeholder material; forming a first contact trench that exposes the first dummy contact; removing the first dummy contact; and forming the middle of line (MOL) metallization to generate the first frontside contact in the region formerly occupied by the first dummy contact and the first contact trench. Optionally, the method includes forming a second dummy contact for a top S/D epi of a second bottom VTFET, wherein the second dummy contact comprises the contact placeholder material; generating a second contact trench that exposes the second dummy contact; removing the second dummy contact; and forming the MOL metallization to generate a second frontside contact (2) that shorts a bottom S/D epi of the first top VTFET to the top S/D epi of the second bottom VTFET to the BEOL interconnect, wherein the second frontside contact is generated in a region formerly occupied by the second dummy contact and the second contact trench.

Example 5 includes the method of example 4, including or excluding optional features. In this example, the method includes forming a second dummy interconnect for a top S/D epi of the first bottom VTFET, wherein the second dummy interconnect comprises the interconnect placeholder material; forming a third contact opening that exposes the second dummy interconnect; removing the second dummy interconnect; and forming backside contact metallization to generate a second backside contact in a region formerly occupied by the second dummy interconnect and the third contact opening. Optionally, the method includes forming a third dummy contact for a gate of a third bottom VTFET, wherein the third dummy contact comprises a contact placeholder material; forming a third contact trench that exposes the third dummy contact; removing the third dummy contact; and forming MOL contact metallization to generate a third frontside contact that occupies a region formerly occupied by the third dummy contact and the third contact trench. Optionally, the method includes forming a fourth dummy contact for a top S/D epi of the third bottom VTFET; forming a fourth contact trench that exposes the fourth dummy contact; removing the fourth dummy contact; and forming MOL contact metallization to generate a fourth frontside contact that occupies a region formerly occupied by the fourth dummy contact and the fourth contact trench. Optionally, the method includes forming the BEOL interconnect; and forming the backside interconnect, wherein the first backside contact is in contact with the first frontside contact, and wherein the first backside contact and first frontside contact wire the bottom S/D epi of the first bottom VTFET to the BEOL interconnect, and wherein the second frontside contact shorts the bottom S/D epi of the first top VTFET to the top S/D epi of the second bottom VTFET to the BEOL interconnect, and wherein the third backside contact wires the top S/D epi of the third bottom VTFET to the backside interconnect through a third local interconnect, and wherein the third frontside contact provides a shared gate contact between the first bottom VTFET and the first top VTFET, and wherein the fourth frontside contact wires the top S/D epi of the third bottom VTFET to the backside interconnect through a fourth local interconnect.

Example 6 is a computer program product comprising program instructions stored on a computer readable storage medium. The computer-readable medium includes instructions that direct the processor to form a first dummy interconnect for a bottom S/D epi of a first bottom VTFET, wherein the first dummy interconnect comprises an interconnect placeholder material; generating a first contact opening that exposes a bottom S/D epi of the first bottom VTFET and the first dummy interconnect; removing the first dummy interconnect; and performing backside contact metallization to generate a first backside contact that wires the bottom S/D epi of the first bottom VTFET to a first local interconnect that is wired to a first frontside contact that is wired to a back end of line (BEOL) interconnect, wherein the first backside contact is generated in a region formerly occupied by the removed first dummy interconnect and the first contact opening. Optionally, the computer-readable medium includes forming a first dummy contact that is in contact with the first dummy interconnect, wherein the first dummy contact comprises a contact placeholder material that is different from the interconnect placeholder material; forming a first contact trench that exposes the first dummy contact; removing the first dummy contact; and forming the middle of line (MOL) metallization to generate the first frontside contact in the region formerly occupied by the first dummy contact and the first contact trench. Optionally, the computer-readable medium includes forming a second dummy contact for a top S/D epi of a second bottom VTFET, wherein the second dummy contact comprises the contact placeholder material; generating a second contact trench that exposes the second dummy contact; removing the second dummy contact; forming the MOL metallization to generate a second frontside contact (2) that shorts a bottom S/D epi of the first top VTFET to the top S/D epi of the second bottom VTFET to the BEOL interconnect, wherein the second frontside contact is generated in a region formerly occupied by the second dummy contact and the second contact trench; forming a second dummy interconnect for a top S/D epi of the first bottom VTFET, wherein the second dummy interconnect comprises the interconnect placeholder material; forming a third contact opening that exposes the second dummy interconnect; removing the second dummy interconnect; forming backside contact metallization to generate a second backside contact in a region formerly occupied by the second dummy interconnect and the third contact opening; forming a third dummy contact for a gate of a third bottom VTFET, wherein the third dummy contact comprises a contact placeholder material; forming a third contact trench that exposes the third dummy contact; removing the third dummy contact; forming MOL contact metallization to generate a third frontside contact that occupies a region formerly occupied by the third dummy contact and the third contact trench; forming a fourth dummy contact for a top S/D epi of the third bottom VTFET; forming a fourth contact trench that exposes the fourth dummy contact; removing the fourth dummy contact; and forming MOL contact metallization to generate a fourth frontside contact that occupies a region formerly occupied by the fourth dummy contact and the fourth contact trench. Optionally, the computer-readable medium includes forming the BEOL interconnect; and forming the backside interconnect, wherein the first backside contact is in contact with the first frontside contact, and wherein the first backside contact and first frontside contact wire the bottom S/D epi of the first bottom VTFET to the BEOL interconnect, and wherein the second frontside contact shorts the bottom S/D epi of the first top VTFET to the top S/D epi of the second bottom VTFET to the BEOL interconnect, and wherein the third backside contact wires the top S/D epi of the third bottom VTFET to the backside interconnect through a third local interconnect, and wherein the third frontside contact provides a shared gate contact between the first bottom VTFET and the first top VTFET, and wherein the fourth frontside contact wires the top S/D epi of the third bottom VTFET to the backside interconnect through a fourth local interconnect.

What is claimed is:

1. A semiconductor device comprising:
a top layer comprising a top vertical-transport field effect transistor (VTFET);
a bottom layer disposed beneath the top layer, wherein the bottom layer comprises a first bottom VTFET; and
a first frontside contact that wires, through a first backside contact and a first local interconnect, a bottom source/drain (S/D) epitaxial (epi) of the first bottom VTFET to a back end of line (BEOL) interconnect.

2. The semiconductor device of claim 1, wherein the bottom layer further comprises a second bottom FET and a backside interconnect, and wherein the semiconductor device further comprises a second frontside contact that shorts a bottom S/D epi of the first top VTFET to a top S/D epi of the second bottom VTFET to the BEOL interconnect.

3. The semiconductor device of claim 2, wherein the bottom layer further comprises a third bottom FET, and wherein the semiconductor device further comprises a third frontside contact that wires a top S/D epi of the third bottom VTFET to the BEOL interconnect.

4. The semiconductor device of claim 3, wherein the first top VTFET is disposed between the second frontside contact and the third frontside contact.

5. The semiconductor device of claim 3, further comprising a fourth frontside contact that provides a shared gate contact between the first bottom VTFET and the first top VTFET.

6. The semiconductor device of claim 5, further comprising a second backside contact that wires a top S/D epi of the third bottom VTFET to the backside interconnect through a third local interconnect.

7. The semiconductor device of claim 6, further comprising a second top VTFET that is wired to the BEOL interconnect through a fifth frontside contact.

8. The semiconductor device of claim 7, further comprising a third top VTFET that is wired to the BEOL interconnect through a sixth frontside contact.

9. The semiconductor device of claim 8, wherein the first frontside contact is disposed between the second top VTFET and the third top VTFET.

10. A method for fabricating a semiconductor device, the method comprising:
forming a first dummy interconnect for a bottom S/D epi of a first bottom VTFET, wherein the first dummy interconnect comprises an interconnect placeholder material;
generating a first contact opening that exposes a bottom S/D epi of the first bottom VTFET and the first dummy interconnect;
removing the first dummy interconnect; and
performing backside contact metallization to generate a first backside contact that wires the bottom S/D epi of the first bottom VTFET to a first local interconnect that is wired to a first frontside contact that is wired to a back end of line (BEOL) interconnect, wherein the first backside contact is generated in a region formerly occupied by the removed first dummy interconnect and the first contact opening.

11. The method of claim 10, further comprising:
forming a first dummy contact that is in contact with the first dummy interconnect, wherein the first dummy contact comprises a contact placeholder material that is different from the interconnect placeholder material;
forming a first contact trench that exposes the first dummy contact;
removing the first dummy contact; and
forming the middle of line (MOL) metallization to generate the first frontside contact in the region formerly occupied by the first dummy contact and the first contact trench.

12. The method of claim 11, further comprising:
forming a second dummy contact for a top S/D epi of a second bottom VTFET, wherein the second dummy contact comprises the contact placeholder material;
generating a second contact trench that exposes the second dummy contact;
removing the second dummy contact; and
forming the MOL metallization to generate a second frontside contact (2) that shorts a bottom S/D epi of the first top VTFET to the top S/D epi of the second bottom VTFET to the BEOL interconnect, wherein the second frontside contact is generated in a region formerly occupied by the second dummy contact and the second contact trench.

13. The method of claim 12, further comprising:
forming a second dummy interconnect for a top S/D epi of the first bottom VTFET, wherein the second dummy interconnect comprises the interconnect placeholder material;
forming a third contact opening that exposes the second dummy interconnect;
removing the second dummy interconnect; and
forming backside contact metallization to generate a second backside contact in a region formerly occupied by the second dummy interconnect and the third contact opening.

14. The method of claim 13, further comprising:
forming a third dummy contact for a gate of a third bottom VTFET, wherein the third dummy contact comprises a contact placeholder material;
forming a third contact trench that exposes the third dummy contact;
removing the third dummy contact; and
forming MOL contact metallization to generate a third frontside contact that occupies a region formerly occupied by the third dummy contact and the third contact trench.

15. The method of claim 14, further comprising:
forming a fourth dummy contact for a top S/D epi of the third bottom VTFET;
forming a fourth contact trench that exposes the fourth dummy contact;
removing the fourth dummy contact; and
forming MOL contact metallization to generate a fourth frontside contact that occupies a region formerly occupied by the fourth dummy contact and the fourth contact trench.

16. The method of claim 15, further comprising:
forming the BEOL interconnect; and
forming the backside interconnect, wherein the first backside contact is in contact with the first frontside contact, and wherein the first backside contact and first frontside contact wire the bottom S/D epi of the first bottom VTFET to the BEOL interconnect, and wherein the second frontside contact shorts the bottom S/D epi of the first top VTFET to the top S/D epi of the second bottom VTFET to the BEOL interconnect, and wherein the third backside contact wires the top S/D epi of the third bottom VTFET to the backside interconnect through a third local interconnect, and wherein the third frontside contact provides a shared gate contact between the first bottom VTFET and the first top VTFET, and wherein the fourth frontside contact wires the top S/D epi of the third bottom VTFET to the backside interconnect through a fourth local interconnect.

17. A computer program product comprising program instructions stored on a computer readable storage medium, the program instructions executable by a processor to cause the processor to perform a method on a wafer, the method comprising:
forming a first dummy interconnect for a bottom S/D epi of a first bottom VTFET, wherein the first dummy interconnect comprises an interconnect placeholder material;
generating a first contact opening that exposes a bottom S/D epi of the first bottom VTFET and the first dummy interconnect;
removing the first dummy interconnect; and
performing backside contact metallization to generate a first backside contact that wires the bottom S/D epi of the first bottom VTFET to a first local interconnect that is wired to a first frontside contact that is wired to a back end of line (BEOL) interconnect, wherein the first backside contact is generated in a region formerly occupied by the removed first dummy interconnect and the first contact opening.

18. The computer program product of claim 17, the method further comprising:
forming a first dummy contact that is in contact with the first dummy interconnect, wherein the first dummy contact comprises a contact placeholder material that is different from the interconnect placeholder material;
forming a first contact trench that exposes the first dummy contact;
removing the first dummy contact; and
forming the middle of line (MOL) metallization to generate the first frontside contact in the region formerly occupied by the first dummy contact and the first contact trench.

19. The computer program product of claim 18, the method further comprising:
forming a second dummy contact for a top S/D epi of a second bottom VTFET, wherein the second dummy contact comprises the contact placeholder material;
generating a second contact trench that exposes the second dummy contact;
removing the second dummy contact;
forming the MOL metallization to generate a second frontside contact (2) that shorts a bottom S/D epi of the first top VTFET to the top S/D epi of the second bottom VTFET to the BEOL interconnect, wherein the second frontside contact is generated in a region formerly occupied by the second dummy contact and the second contact trench;
forming a second dummy interconnect for a top S/D epi of the first bottom VTFET, wherein the second dummy interconnect comprises the interconnect placeholder material;
forming a third contact opening that exposes the second dummy interconnect;
removing the second dummy interconnect;
forming backside contact metallization to generate a second backside contact in a region formerly occupied by the second dummy interconnect and the third contact opening;
forming a third dummy contact for a gate of a third bottom VTFET, wherein the third dummy contact comprises a contact placeholder material;
forming a third contact trench that exposes the third dummy contact;
removing the third dummy contact;
forming MOL contact metallization to generate a third frontside contact that occupies a region formerly occupied by the third dummy contact and the third contact trench;
forming a fourth dummy contact for a top S/D epi of the third bottom VTFET;
forming a fourth contact trench that exposes the fourth dummy contact;
removing the fourth dummy contact; and
forming MOL contact metallization to generate a fourth frontside contact that occupies a region formerly occupied by the fourth dummy contact and the fourth contact trench.

20. The computer program product of claim 19, further comprising:
forming the BEOL interconnect; and
forming the backside interconnect, wherein the first backside contact is in contact with the first frontside contact, and wherein the first backside contact and first frontside contact wire the bottom S/D epi of the first bottom VTFET to the BEOL interconnect, and wherein the second frontside contact shorts the bottom S/D epi of the first top VTFET to the top S/D epi of the second bottom VTFET to the BEOL interconnect, and wherein the third backside contact wires the top S/D epi of the third bottom VTFET to the backside interconnect through a third local interconnect, and wherein the third frontside contact provides a shared gate contact between the first bottom VTFET and the first top VTFET, and wherein the fourth frontside contact wires the top S/D epi of the third bottom VTFET to the backside interconnect through a fourth local interconnect.
